(19) United States
(12) Patent Application Publication
(10) Pub. No.: US 2024/0429044 A1
(43) Pub. Date: Dec. 26, 2024

(54) SUBSTRATE PROCESSING METHOD

(71) Applicant: ASM IP Holding B.V., Almere (NL)

(72) Inventors: Yan Zhang, Tokyo (JP); Ryu Nakano, Sagamihara-shi (JP)

(21) Appl. No.: 18/746,827

(22) Filed: Jun. 18, 2024

Related U.S. Application Data
(60) Provisional application No. 63/522,821, filed on Jun. 23, 2023.

(51) Int. Cl. H01L 21/02; H01J 37/32; H01L 21/768

(52) U.S. Cl. CPC H01L 21/0228; H01J 37/32449; H01L 21/02164; H01L 21/02274; H01L 21/76877; H01J 2237/3321

(57) ABSTRACT

Provided is a method of filling a gap formed on a substrate, the method comprising the steps of providing the substrate onto a substrate support in a reaction chamber, forming a film on the substrate comprising the steps of supplying a first gas to the reaction chamber and supplying a second gas to the reaction chamber, and treating the film formed on the substrate comprising the steps of supplying a third gas to the reaction chamber and supplying a fourth gas to the reaction chamber, wherein the second gas and the fourth gas are activated in-situ and the third gas is activated remotely.

### CROSS-REFERENCE TO RELATED APPLICATIONS

This application claims priority to U.S. Provisional Patent Application Ser. No. 63/522,821 filed Jun. 23, 2023 titled SUBSTRATE PROCESSING METHOD, the disclosure of which is hereby incorporated by reference in its entirety.

### FIELD OF INVENTION

The disclosure relates to a process for forming a semiconductor film, particularly to a method of filling a gap with the semiconductor film while using an inhibitor effectively.

### BACKGROUND OF THE DISCLOSURE

A conventional PECVD (Plasma Enhanced Chemical Vapor Deposition) method has been used to fill gap structures such as STI (Shallow Trench Isolation) in semiconductor devices. As a size of the device shrinks, a line width of the circuit becomes narrower. The PECVD method, however, forms a film mostly at a top portion of the gap and obstructs filling a lower portion of the gap. Therefore, a void is generated in the gap as shown in FIG. 1. In FIG. 1, a gap 2 formed on the substrate 1 may be filled with a film 3 by PECVD method with a void generated in the gap 2.

On the other hand, a PEALD (Plasma Enhanced Atomic Layer Deposition) method may be employed to fill a gap instead of PECVD method. A PEALD method enables a film to be formed conformally along a surface of the gap. But as the gap becomes deeper and the entrance thereof becomes narrower, it is harder for source gas to travel to the lower portion of the gap, resulting in a void in the gap.

To solve that problem, an inhibitor is employed in PEALD method. The inhibitor prevents formation of a film on an upper portion of the gap. Therefore, an entrance of the gap is wide open compared to the lower portion of the gap, resulting in a void-free gap fill process. A conventional inhibiting process for filling the gap comprises supplying an activated inhibiting gas such as nitrogen radicals, followed by forming a film thereon as illustrated in FIG. 2.

In FIG. 2, a film 5 may be formed on the gap 2 of the substrate 1 with a gap 2 (step 1). Then an inhibitor may be supplied to the substrate and an inhibiting layer 6 may be formed at the upper portion of the gap 2 (step 2). The inhibitor may comprise nitrogen radicals generated in-situ. The step 1 and the step 2 are repeated. Since the inhibiting layer 6 is already formed at the upper portion of the gap, a film formation may be suppressed at the upper portion, compared to the lower portion of the gap as shown in step 3. In other words, the entrance of the gap may be wide open and a bottom-up fill may be carried out. The step 1 to the step 3 may be repeated until the gap is fully filled without a void (step 4).

However, the conventional inhibiting process has a limitation in filling a gap with high aspect ratio and narrow entrance. Filling such a gap requires much stronger inhibiting features at the upper portion of the gap. To that end, a higher plasma power is applied to the reaction chamber in supplying an inhibitor, but it causes undesired damage to the substrate and the reaction chamber as well as film delamination. Thus, a gap filling method that avoids these effects is desired.

### SUMMARY OF THE DISCLOSURE

The disclosure discloses a method of filling a gap. The disclosure particularly discloses a method of filling a gap using an inhibitor more effectively by employing an in-situ plasma and a remote plasma.

In one or more embodiments, a method of filling a gap formed on a substrate may comprise the step of providing the substrate onto a substrate support in a reaction chamber, the step of forming a film on the substrate and the step of treating the film formed on the substrate.

In one or more embodiments, the step of forming the film on the substrate may comprise supplying a first gas in the reaction chamber and supplying a second gas in the reaction chamber.

In one or more embodiments, the step of treating the film on the substrate may comprise supplying a third gas in the reaction chamber and supplying a fourth gas in the reaction chamber.

In one or more embodiments, the second gas and the fourth gas may be activated in-situ and the third gas may be activated remotely.

In one or more embodiments, the first gas may comprise one or more of: an aminosilane, an iodosilane, or a silicon halide.

In one or more embodiments, the first gas may comprise at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N (tBu); DEAS, SiH₃NEt₂; DTBAS, SiH₃N (tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; DIPAS, SiH₃N(iPr)₂; TEOS, Si(OEt)₄; SiCl₄; HCD, Si₂Cl₆; 3DMAS, SiH(N(Me)₂)₃; BEMAS, SiH₂[N(Et)(Me)]₂; AHEAD, Si₂(NHEt)₆; TEAS, Si(NHEt)₄; Si₃H₈; DCS, SiH₂Cl₂; SiHI₃; SiH₂I₂, a derivative thereof, or a mixture thereof.

In one or more embodiments, the second gas may comprise an oxygen-containing gas.

In one or more embodiments, the second gas may comprise at least one of O₂, NO, N₂O, NO₂, O₃, or a mixture thereof.

In one or more embodiments, the third gas may comprise a nitrogen-containing gas.

In one or more embodiments, the third gas may comprise at least one of N₂, NH₃, NH₄, N₂H₂, N₂H₄, or a mixture thereof.

In one or more embodiments, the third gas may be activated in a remote chamber and supplied to the reaction chamber.

In one or more embodiments, the fourth gas may comprise an inert gas.

In one or more embodiments, the fourth gas may be supplied throughout the step of forming the film and the step of treating the film, and the third gas and the fourth gas may be activated simultaneously.

In one or more embodiments, a cycle ratio of the step of forming the film to the step of treating the film may be 1:5 or less.

In one or more embodiments, a substrate processing chamber to process a substrate with a gap may comprise a reaction chamber, a remote chamber connected to the reaction chamber and a plurality of gas supply lines connected to the reaction chamber and the remote chamber.

In one or more embodiments, the substrate processing chamber may further comprise a first power source connected to the reaction chamber, a second power source connected to the remote chamber and a main controller to control the first power source and the second power source.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIG. 1 illustrates a gap fill process by a conventional PECVD method.

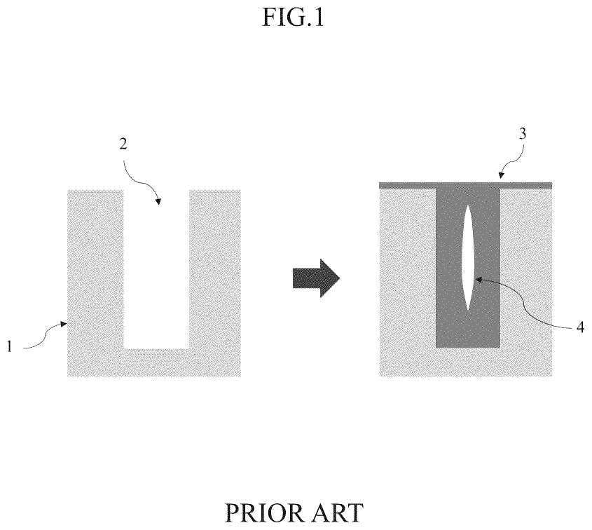

FIG. 2 illustrates a conventional inhibiting process for filling the gap.

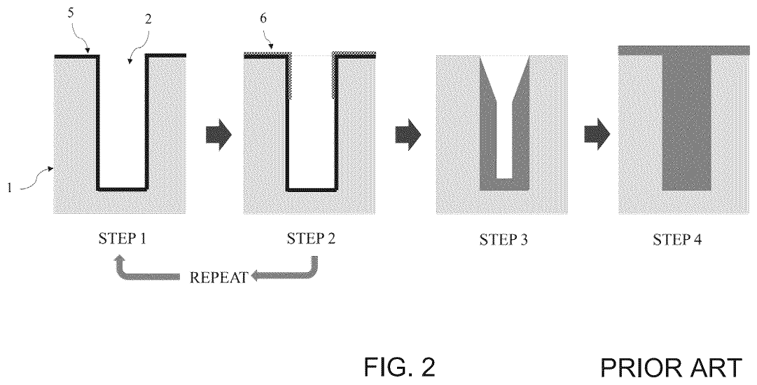

FIG. 3 illustrates a process flow for at least one embodiment of the disclosure.

FIG. 4 illustrates a timing graph for at least one embodiment of the disclosure.

FIG. 5 A to C illustrates a reaction mechanism on the substrate at the step of treating a film.

FIG. 6 shows an inhibiting feature on SiO₂ film by a treatment condition.

FIG. 7 illustrates film profiles from the top to the bottom of the gap by each condition illustrated in FIG. 6.

FIG. 8 is TEM (Transmission Electron Microscopy) images showing an inhibiting +capability of each condition of FIG. 6 and FIG. 7.

FIG. 9 illustrates a substrate processing chamber of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

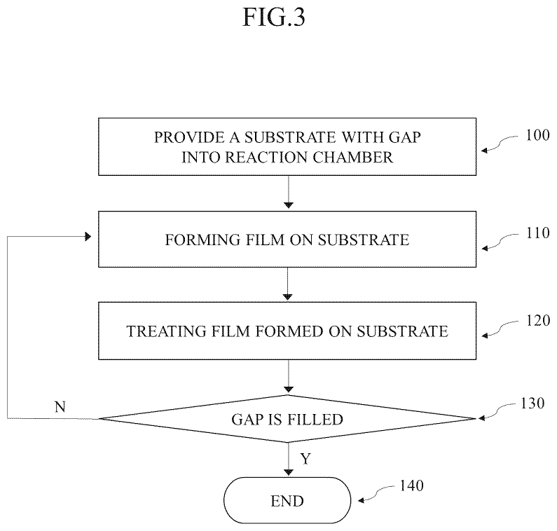

FIG. 3 illustrates a process flow for the process of the disclosure. Each step of FIG. 3 will be described in more detail as below.

In step 100 of FIG. 3, a substrate comprising a gap may be provided onto a substrate support in a reaction chamber. The gap may be a trench with high aspect ratio. For instance, the gap may have a high aspect ratio of 20:1 or more.

In step 110, a film may be formed on the substrate. The film may be a SiO₂ film formed by PEALD method. The film may be formed by supplying a first gas and a second gas sequentially and alternately. For instance, the first gas may be a silicon source gas and the second gas may be an oxygen-containing gas. The second gas may be further activated in situ (i.e. applying a power to the electrode disposed in the reaction chamber). The intensity of the power applied to the reaction chamber may be between about 50 W and about 400 W, or between about 100 W and 300 W.

The step 110 may be repeated a plurality of times.

The first gas may comprise one or more of an aminosilane, an iodosilane, or a silicon halide. For instance, the first gas may comprise at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N (tBu); DEAS, SiH₃NEt₂; DTBAS, SiH₃N (tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; DIPAS, SiH₃N(iPr)₂; TEOS, Si(OEt)₄; SiCl₄; HCD, Si₂Cl₆; 3DMAS, SiH(N(Me)₂)₃; BEMAS, SiH₂[N(Et)(Me)]₂; AHEAD, Si₂(NHEt)₆; TEAS, Si(NHEt)₄; Si₃H₈; DCS, SiH₂Cl₂; SiHI₃; SiH₂I₂, a derivative thereof, or a mixture thereof.

The second gas may comprise at least one of O₂, NO, N₂O, NO₂, O₃, or a mixture thereof.

In step 120, treating the film formed on the substrate may be carried out.

In step 120, the treatment may be carried out by supplying a third gas to a remote chamber connected to the reaction chamber through a gas supply line and activating the third gas ex-situ (i.e. applying a power to the remote chamber). After that, the activated third gas may be supplied to the reaction chamber. The intensity of the power applied to the remote chamber may be between about 1,000 W and about 10,000 W, or between about 2,000 W and about 8,000 W. In one embodiment of the disclosure, the remote chamber may comprise a remote plasma unit.

In another embodiment, Ar may be further supplied to the remote chamber along with the third gas to stabilize a remote plasma.

The step 120 may be repeated a plurality of times.

In step 120, the treatment may further comprise supplying a fourth gas to the reaction chamber and activating the fourth gas by supplying a power to the reaction chamber. To that end, a power of between about 50 W and about 400 W, or between about 100 W and about 300 W may be applied to the reaction chamber. That is, in step 120, the third gas may be supplied to the remote chamber, activated and flow to the reaction chamber, and the fourth gas may be supplied to the reaction chamber and activated. In one embodiment, the third gas and the fourth gas may be activated simultaneously.

The third gas may inhibit a film from being formed on the substrate, particularly at the upper portion of the gap. More specifically, the third gas may be an inhibitor and the third gas supplied to the substrate may form an inhibiting layer at the upper portion of the gap.

The third gas may comprise a nitrogen-containing gas and may comprise at least of one of N₂, NH₃, NH₄, N₂H₂, N₂H₄, or a mixture thereof.

The fourth gas may comprise an inert gas such as Ar and He. The fourth gas may be supplied continuously to the reaction chamber throughout the step 100 to the step 120. In one embodiment, the fourth gas may be a carrier gas of the first gas and a purge gas.

The step 110 may be repeated a plurality of times and the cycle ratio of the step 110 to the step 120 may be 5:1 or less.

The step 130 determines whether the gap is filled with the film without a void. If the gap is not filled yet, then the step 110 and the step 120 are repeated until the gap is filled. If the gap is filled without a void, the process may end (i.e. the step 140).

The step 110 to the step 130 may be carried at between about 200° C. and about 400° C., or between about 250° C. and 350° C. in the reaction chamber.

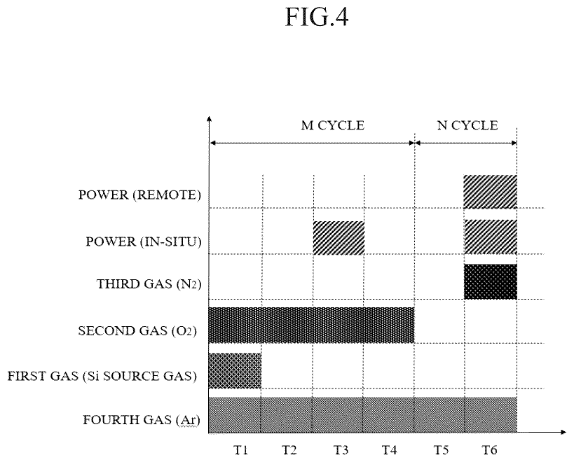

FIG. 4 illustrates a timing graph for the process of the disclosure.

In FIG. 4, the step T1 to the step T4 is a step for forming a SiO₂ film on the substrate and corresponds to the step 110 of FIG. 3. The step T5 to the step T6 is a step for treating the SiO₂ film formed on the substrate and corresponds to the step 120 of FIG. 3.

As illustrated in FIG. 4, the step for forming a SiO₂ film (i.e. T1 to T4) may be carried out by PEALD method and a power is applied to the reaction chamber in-situ at the step T3 in order to activate an oxygen-containing gas (e.g. O₂). The step T1 to the step T4 may be repeated a plurality of times (i.e. M cycles).

The step for treating the SiO₂ film (i.e. T5 to T6) may be carried out by supplying and activating a third gas. The third gas may be a nitrogen-containing gas such as N₂ and activated by applying a power to the remote chamber remotely at the step T6 and is supplied to the reaction chamber. The step T5 to the step T6 may be repeated a plurality of times (i.e. N cycles). Also as illustrated in FIG. 4, a fourth gas (e.g. Ar) may be further activated in-situ in the reaction chamber simultaneously at the step T6.

The step 110 may be repeated a plurality of times and the cycle ratio of the step 110 to the step 120 (M:N) may be 5:1 or less.

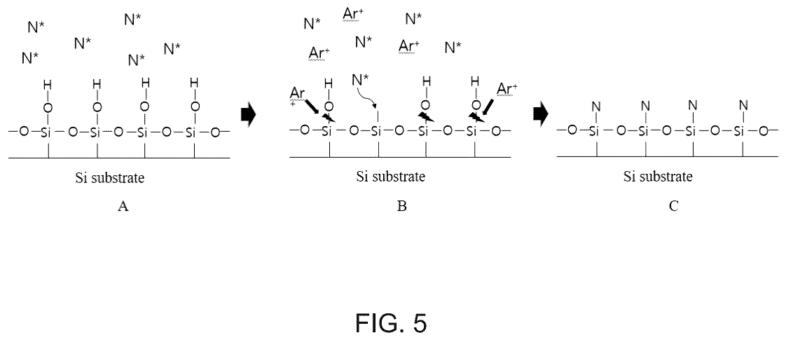

FIG. 5 A to C illustrates a reaction mechanism on the substrate at the step of treating a film.

FIG. 5 A illustrates supplying only remotely activated nitrogen radicals. The radicals, however, may have weak reactivity with the substrate (i.e. —OH sites) since there may be deactivation of the nitrogen radicals as they travel to the substrate. Therefore, an inhibiting layer may not be formed on the surface of the substrate.

FIG. 5 B illustrates further supplying argon radicals.

In FIG. 5 B, Ar ions break the bond between —OH and —Si and remove the —OH from the bond, leaving a —Si dangling bond. The Ar is activated in-situ, and therefore it may have an energy enough to break the Si—OH bond by ion bombardment. After that, the nitrogen radicals may react with the —Si dangling bond. In one embodiment of the disclosure, the remote activation of nitrogen as shown in FIG. 5 A and the in-situ activation of Ar as shown in FIG. 5B may be carried out simultaneously.

FIG. 5 C illustrates the surface of the substrate after the treatment. As shown in FIG. 5C, a Si—N layer is formed on the surface of the substrate. The nitrogen may inhibit the Si source gas from adsorbing on the substrate in the subsequent cycles. Thus, the Si—N layer is referred to as an inhibiting layer.

In FIG. 5 B to C, Ar ions may break the Si—OH bonding and assist nitrogen radicals to react with the —Si dangling bonds. Thus, the disclosure has a technical benefit that a desired inhibiting feature may be achieved without applying a high power to the inhibiting gas in filling a gap with high aspect ratio.

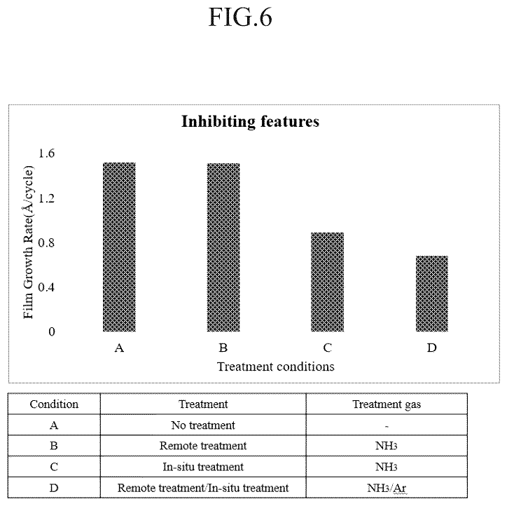

In FIG. 6, an inhibitor feature is identified by measuring the SiO₂ film growth rate under each of four treatment conditions A-D.

The condition A does not carry out a treatment. In other words, the condition A just carries out forming a SiO₂ film on the substrate. The condition A shows the highest film growth rate as no inhibitor is supplied to the substrate.

The condition B carries out forming a SiO₂ film, followed by treating the SiO₂ film with remotely activated NH₃. As shown in the graph, the SiO₂ film growth rate at condition B is almost the same as the SiO₂ film growth rate at condition A. Thus, it indicates that a remotely activated inhibitor may have low inhibiting ability. In other words, the inhibitor may not have an energy enough to break the Si—OH bond.

The condition C carries out forming a SiO₂ film, followed by treating the SiO₂ film with in-situ activated NH₃. As shown in the graph, the SiO₂ film growth rate at condition C is significantly lower than the SiO₂ film growth rate at condition B. Thus, it indicates that the inhibitor activated in-situ may have an energy enough to break the Si—OH bond and have a higher inhibiting ability when compared to the condition B.

The condition D carries out forming a SiO₂ film, followed by treating the SiO₂ film with NH₃ activated remotely and Ar activated in-situ simultaneously. As shown in the graph, the SiO₂ film growth rate at condition D is even lower than the SiO₂ film growth rate at condition C. Thus, it indicates that the inhibitor at condition D may have more energy enough to break the Si—OH bond and have more enhanced inhibiting ability than that of condition C.

Therefore, from FIG. 6, the disclosure has a technical benefit that the treatment with inhibitor activated remotely and inert gas activated in-situ may enable to achieve more enhanced inhibiting feature.

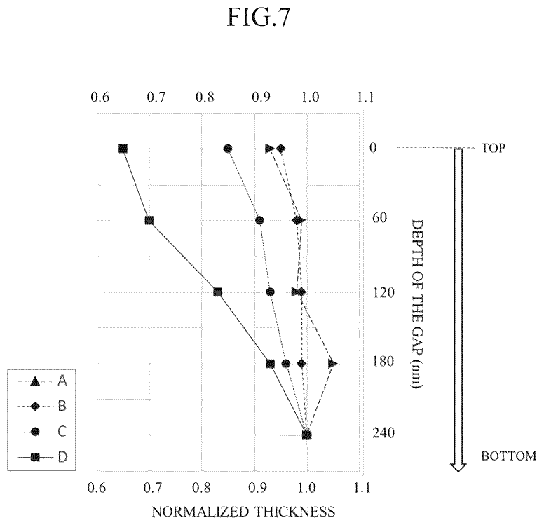

FIG. 7 illustrates film profiles from the top to the bottom of the gap by each condition illustrated in FIG. 6.

As shown in FIG. 7, the thickness of SiO₂ film formed on the sidewall of the gap by the depth varies depending on the treatment condition.

In FIG. 7, a treatment under the condition B (i.e., supplying only NH₃ activated remotely) may still result in a thick SiO₂ film at the upper portion of the gap, almost the same as the SiO₂ film thickness under the condition A (i.e. the normalized thickness is 0.95 for the condition B and 0.93 for the condition A). In other words, supplying a remotely activated inhibitor may have low inhibiting ability.

A treatment under the condition C (i.e., supplying activated in-situ NH₃) results in a thinner SiO₂ film than the condition B at the upper portion of the gap (i.e. the normalized thickness is 0.85 for the condition C and 0.95 for the condition B). As described above, an inhibitor activated in-situ may have more energy to break the Si—OH bond and react with the —Si dangling bond than an inhibitor activated remotely. Therefore, the treatment under the condition C may have stronger inhibiting ability than the condition B.

A treatment under the condition D (i.e. supplying NH₃ activated remotely and supplying Ar activated in-situ simultaneously) results in a much thinner SiO₂ film than the condition C at the upper portion of the gap (i.e. the normalized thickness are 0.65 for the condition D and 0.85 for the condition C). In other words, the gap entrance may be wide open more than the condition C. Therefore, the condition D may have much stronger inhibiting ability than other treatment conditions.

As described above, as the step coverage of the gap becomes higher and the width of the gap becomes narrower, more power is required to increase the inhibiting capability. However, applying more power to activate the inhibitor in-situ in the reaction chamber may result in damage to the substrate and the reaction chamber. On the other hand, only applying a power to activate the inhibitor remotely may result in low inhibiting capability as shown in FIG. 6 and FIG. 7. Therefore, a treatment method of the disclosure, that is, activating the inhibitor remotely and activating the Ar in-situ simultaneously have a technical benefit of enhancing the inhibiting capability more, reducing the damage to the substrate and the reaction chamber.

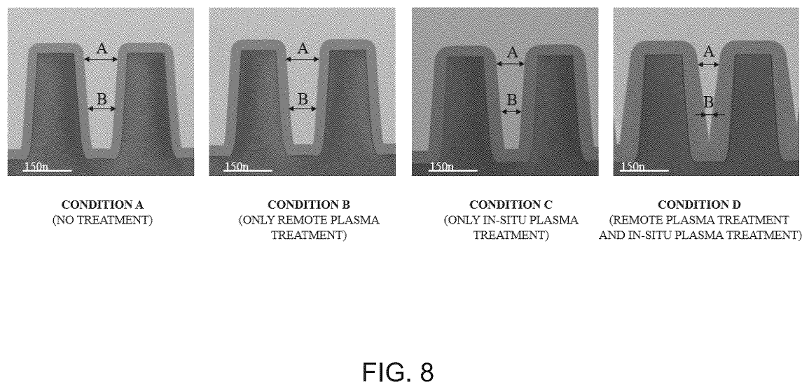

FIG. 8 is TEM (Transmission Electron Microscopy) images showing an inhibiting capability of each condition of FIG. 6 and FIG. 7.

As shown in FIG. 8, the condition D shows that the difference of the width between the upper portion and the lower portion of the gap (i.e. A-B) is bigger than other conditions. In other words, carrying out the in-situ treatment and the remote treatment simultaneously may have the strongest inhibiting capability compared to other conditions.

Table 1 is the test conditions for one embodiment of the disclosure.

TABLE 1
Test conditions for one embodiment of the disclosure

| | | Film forming step | Treatment step |
|---|---|---|---|
| Gas flow rate | Source Carrier Ar | 1,000 to 6,000 | — |
| (sccm) | (First gas) | (preferably | |
| | | 2,000 to 5,000) | |
| | Purge Ar | 1,000 to 3,000 | — |
| | (Fourth gas) | (preferably | |
| | | 1,500 to 2,500) | |
| | RPU (Remote | — | 1,000 to 6,000 |
| | Plasma Unit) Ar | | (preferably |
| | | | 2,000 to 5,000) |
| | O₂ (Second gas) | 1,000 to 3,000 | — |
| | | (preferably | |
| | | 1,500 to 2,500) | |
| | N₂ (Third gas) | — | 500 to 2,000 |
| | | | (preferably |
| | | | 1,000 to 1,500) |
| | NH₃ (Third gas) | — | 10 to 50 |
| | | | (preferably |
| | | | 20 to 40) |
| Process | Source feeding | 0.1 to 1.0 | — |
| time (sec) | | (preferably | |
| | | 0.2 to 0.8) | |
| | Source purge | 0.5 to 2.0 | — |
| | | (preferably | |
| | | 0.8 to 1.6) | |
| | RF-ON | 0.5 to 2.0 | 1.0 to 10.0 |
| | | (preferably | (preferably |
| | | 0.8 to 1.6) | 2.0 to 8.0) |
| | purge | 0.01 to 0.1 | — |
| | | (preferably | |
| | | 0.02 to 0.08) | |
| Plasma | RF power to the | 50 to 400 | 50 to 400 |
| condition | reaction chamber | (preferably | (preferably |
| | (W) | 100 to 300) | 100 to 300) |
| | RF power to the | — | 1,000 to 10,000 |
| | remote chamber | | (preferably |
| | (W) | | 2,000 to 8,000) |

| | |
|---|---|
| Temperature (° C.) | 200° C. to 400° C. |
| | (preferably 250° C. to 350° C.) |
| Cycle ratio | 1:1 to 5:1 |
| Silicon precursor | Aminosilane |

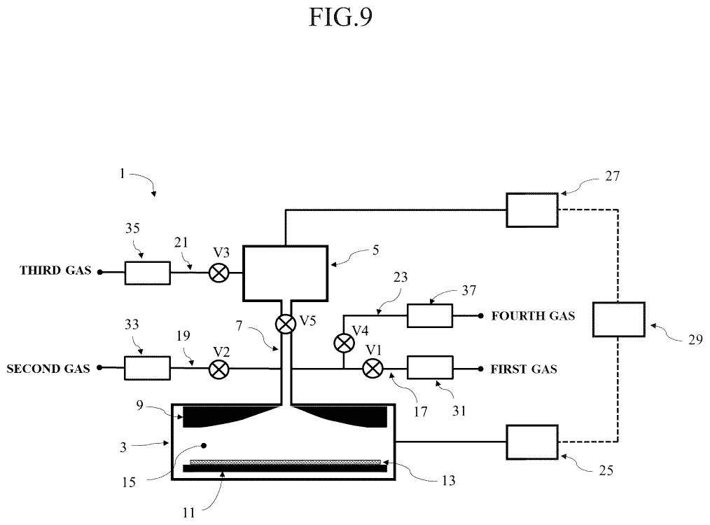

FIG. 9 illustrates a substrate processing chamber of the disclosure.

In FIG. 9, a substrate processing chamber 1 may comprise a reaction chamber 3, a remote chamber 5, a connecting unit 7 connecting the reaction chamber 3 with the remote chamber 5 and a gas supply unit. The gas supply unit may comprise a first gas supply line 17, a second gas supply line 19, a third gas supply line 21 and a fourth gas supply line 23.

The first gas supply line 17 supplies a first gas to the reaction chamber 3, the second gas supply line 19 supplies a second gas to the reaction chamber 3, the third gas supply line 21 supplies a third gas to the remote chamber 5, and the fourth gas supply line 23 supplies a fourth gas to the reaction chamber 3.

The gas supply unit may further comprise a first gas flow control unit for the first gas supply line, a second gas flow control unit for the second gas supply line, a third gas flow control unit for the third gas supply line and a fourth gas flow control unit for the fourth gas supply line.

The first gas flow control unit may comprise a first gas flow controller 31 and a first valve V1. The second gas flow control unit may comprise a second gas flow controller 33 and a second valve V2. The third gas flow control unit may comprise a third gas flow controller 35 and a third valve V3. The fourth gas flow controller may comprise a fourth gas flow controller 37 and a fourth valve V4.

The connecting unit 7 may further comprise a fifth valve V5 in order to open and/or close the connecting unit 7.

The reaction chamber 3 may further comprise a gas injection unit 9 and a substrate support 11. The gas injection unit 9 and the substrate support 11 may be disposed to form a reaction space 15. The gas injection unit 9 may comprise a showerhead plate, or in other embodiment, the gas injection unit may comprise a corn-shaped or a quarter elliptical wall with a curved surface in order to distribute a gas to the substrate more evenly. The gas injection unit 9 may act as an electrode to which a power may be applied to form a plasma in-situ.

The substrate processing chamber 1 may further comprise a power supply unit to supply a power to the reaction chamber and the remote chamber.

The power supply unit may comprise a first power source 25 connected to the reaction chamber 3, a second power source 27 connected to the remote chamber 5 and a controller 29 to control the first power source 25 and the second power source 27.

The controller 29 may control the first power source 25 to apply a power to the electrode (e.g. the gas injection unit 9) reaction chamber 3 in the film forming step in order to generate a plasma in the reaction space 15. The controller 29 may also control the first power source 25 and the second power source 27 to apply a power to the reaction chamber 3 and the remote chamber 5 simultaneously in the treatment step.

As described above, during the film forming step, the first gas, the second gas and the fourth gas may be supplied to the reaction chamber 3 and the first power source 25 may apply a power to the reaction chamber 3.

During the treatment step, the third gas may be supplied to the remote chamber 5 and the second power source 27 may apply a power to the remote chamber 5. In one embodiment of the disclosure, the remote chamber may comprise a remote plasma unit. The activated third gas may flow to the reaction chamber 3 through the connecting unit 7. In another embodiment, Ar may be further supplied to the remote chamber to stabilize a remote plasma. The fourth gas may also be supplied to the reaction chamber 3 and be activated by a power applied to the reaction chamber 3 from the first power source 25. The third gas and the fourth gas may be activated simultaneously in the treatment step.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A method of filling a gap formed on a substrate, the method comprising:
providing the substrate onto a substrate support in a reaction chamber;
forming a film on the substrate, comprising:
supplying a first gas to the reaction chamber;
supplying a second gas to the reaction chamber; and
treating the film formed on the substrate, comprising:
supplying a third gas in the reaction chamber; and
supplying a fourth gas in the reaction chamber,
wherein the second gas and the fourth gas are activated in-situ and the third gas is activated remotely.

2. The method of claim 1, wherein the first gas comprises one or more of: an aminosilane, an iodosilane, or a silicon halide.

3. The method of claim 2, wherein the first gas comprises at least one of TSA, (SiH₃)₃N; DSO, (SiH₃)₂; DSMA, (SiH₃)₂NMe; DSEA, (SiH₃)₂Net; DSIPA, (SiH₃)₂N(iPr); DSTBA, (SiH₃)₂N (tBu); DEAS, SiH₃Net₂; DTBAS, SiH₃N (tBu)₂; BDEAS, SiH₂(Net₂)₂; BDMAS, SiH₂(Nme₂)₂; BTBAS, SiH₂(NhtBu)₂; BITS, SiH₂(NHSiMe₃)₂; DIPAS, SiH₃N(iPr)₂; TEOS, Si(Oet)₄; SiCl₄; HCD, Si₂Cl₆; 3DMAS, SiH(N(Me)₂)₃; BEMAS, SiH₂[N(Et)(Me)]₂; AHEAD, Si₂(NHEt)₆; TEAS, Si(NHEt)₄; Si₃H₈; DCS, SiH₂Cl₂; SiHI₃; SiH₂I₂, a derivative thereof, or a mixture thereof.

4. The method of claim 1, wherein the second gas comprises an oxygen-containing gas.

5. The method of claim 4, wherein the second gas comprises at least one of O₂, NO, N₂O, NO₂, O₃, or a mixture thereof.

6. The method of claim 1, wherein the third gas comprises a nitrogen-containing gas.

7. The method of claim 6, wherein the third gas comprises at least one of N₂, NH₃, NH₄, N₂H₂, N₂H₄, or a mixture thereof.

8. The method of claim 1, wherein the fourth gas comprises an inert gas.

9. The method of claim 1, wherein a power of between about 50 W and about 400 W, or a power of between about 100 W and about 300 W is applied to the reaction chamber in the step of supplying the second gas and the step of supplying the fourth gas.

10. The method of claim 1, wherein the third gas is activated in a remote chamber and supplied to the reaction chamber.

11. The method of claim 1, wherein the fourth gas is supplied throughout the step of forming the film and the step of treating the film, and the third gas and the fourth gas are activated simultaneously.

12. The method of claim 10, wherein a power of between about 1,000 W and about 10,000 W, or a power of between about 2,000 W and about 8,000 W is applied to the remote chamber.

13. The method of claim 1, wherein the step of forming the film is repeated a plurality of times.

14. The method of claim 13, wherein a cycle ratio of the step of forming the film to the step of treating the film is 5:1 or less.

15. The method of claim 14, wherein the step of forming the film and the step of treating the film are repeated a plurality of times until the gap is filled with the film.

16. The method of claim 1, wherein a temperature of the substrate support within the reaction chamber is between about 200° C. and about 400° C., or between about 250° C. and 350° C.

17. A substrate processing chamber to process a substrate with a gap, comprising
a reaction chamber;
a remote chamber connected to the reaction chamber;
a connecting unit connecting the reaction chamber with the remote chamber;
a gas supply unit connected to the reaction chamber and the remote chamber; and
a power supply unit to supply a power to the reaction chamber and the remote chamber, wherein the power supply unit comprises:
a first power source connected to the reaction chamber;
a second power source connected to the remote chamber; and
a controller to control the first power source and the second power source.

18. The substrate processing chamber of claim 17, wherein the gas supply unit comprises a first gas supply line, a second gas supply line, a third gas supply line and a fourth gas supply line,
wherein, the first gas supply line supplies a first gas to the reaction chamber, the second gas supply line supplies a second gas to the reaction chamber, the third gas supply line supplies a third gas to the remote chamber, and the fourth gas supply line supplies a fourth gas to the reaction chamber.
Wherein, the gas supply unit further comprise a first gas flow control unit for the first gas supply line, a second gas flow control unit for the second gas supply line, a third gas flow control unit for the third gas supply line and a fourth gas flow control unit for the fourth gas supply line.

19. The substrate processing chamber of claim 18, the controller controls the first power source and the second power source to apply a power to the reaction chamber and the remote chamber simultaneously.

20. The substrate processing chamber of claim 17, wherein the substrate processing chamber is configured to perform the method of claim 1.
